(19) United States
(12) Patent Application Publication
(10) Pub. No.: US 2024/0224645 A1
(43) Pub. Date: Jul. 4, 2024

(54) DISPLAY DEVICE

(71) Applicant: LG Display Co., Ltd., Seoul (KR)

(72) Inventors: InYeong Kong, Seoul (KR); YoungMin Jeong, Paju-si (KR); ByungSam Min, Goyang-si (KR)

(73) Assignee: LG Display Co., Ltd., Seoul (KR)

(21) Appl. No.: 18/368,693

(22) Filed: Sep. 15, 2023

(30) Foreign Application Priority Data
Dec. 30, 2022 (KR) 10-2022-0190782

(51) Int. Cl. H10K 59/131; H10K 71/00; H10K 71/50

(52) U.S. Cl. CPC H10K 59/131; H10K 71/50; H10K 71/861; H10K 2102/341

(57) ABSTRACT

A display device including a substrate with an emission area and a non-emission area; a plurality of sub pixels in the emission area; a driving circuit including a plurality of transistors and wiring lines in the non-emission area for selectively driving each sub pixel; and a reference line extending in the emission area between two adjacent sub pixels and including a plurality of branch lines branching from the reference line and being connected to a respective transistor included in the driving circuit for transmitting a reference signal to each subpixel. Further, each branch line comprises a laminated semiconductor layer and transparent oxide layer extending along the emission area and crossing into the non-emission area. In addition, an opaque metal layer is provided on the transparent oxide layer of a corresponding branch line at a position in the non-emission area.

### CROSS-REFERENCE TO RELATED APPLICATIONS

This application claims priority to Korean Patent Application No. 10-2022-0190782, filed on Dec. 30, 2022, in the Republic of Korea, the entire contents of which is hereby incorporated herein by reference into the present application.

### BACKGROUND

### Field

The present disclosure relates to a display device, and more particularly, to a display device including a repair unit having a laminated structure for stably repairing while implementing a high aperture ratio.

### Description of the Related Art

Various display devices are slim, light weight, and require low power consumption. A representative display device includes a liquid crystal display (LCD) device, a field emission display (FED) device, an electro-wetting display (EWD) device, an organic light emitting display (OLED) device, etc.

Among them, the OLED device is a self-emitting display device so that a separate light source is not needed, which is different from the liquid crystal display device. Therefore, the OLED device can be manufactured to have a light weight and a small thickness. Further, the OLED device is advantageous not only in terms of power consumption due to the low voltage driving, but also in terms of color implementation, a response speed, a viewing angle, and a contrast ratio (CR).

### SUMMARY

Accordingly, one object of the present disclosure is to provide a display device with an improved aperture ratio by configuring a branch line with a transparent material.

Another object of the present disclosure is to provide a display device having a repair unit without additionally individually disposing a metal layer in a branch line.

Still another object of the present disclosure is to provide a display device in which a repair process can be performed without degrading the aperture ratio.

Objects of the present disclosure are not limited to the above-mentioned objects, and other objects, which are not mentioned above, can be clearly understood by those skilled in the art from the following descriptions.

According to an aspect, the present disclosure provides a display device including a substrate with an emission area and a non-emission area are included and a plurality of sub pixels is defined, at least one gate line in the non-emission area, at least one signal line which is in the non-emission area and intersects the at least one gate line, at least one branch line which is connected to the at least one signal line and a repair unit which is on a partial branch line corresponding to a repair area, among the at least one branch line, to be in direct contact with the branch line.

A branch line extending from the signal line is configured by a semiconductor layer and a transparent oxide layer so that a transparency is provided to ensure a wider opening area. Further, the repair process can be stably performed on the signal line while ensuring a high aperture ratio.

Also, an aperture ration can be maximized without additionally disposing a separate opaque metal layer. The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic block diagram of a display device according to an embodiment of the present disclosure;

FIG. 2 is a circuit diagram of a sub pixel of a display device according to an embodiment of the present disclosure;

FIG. 3 is an enlarged plan view of a display device according to an embodiment of the present disclosure;

FIG. 4 is an enlarged view of an area A of FIG. 3; and

FIGS. 5A and 5B are cross-sectional views taken along the line V-V′ of FIG. 4.

### DETAILED DESCRIPTION OF THE EMBODIMENT

Advantages and characteristics of the present disclosure and a method of achieving the advantages and characteristics will be clear by referring to embodiments described below in detail together with the accompanying drawings. However, the present disclosure is not limited to the embodiments disclosed herein and can be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated. When the position relation between two parts is described using the terms such as “on,” “above,” “below,” and “next,” one or more parts can be positioned between the two parts unless the terms are used with the term “immediately” or “directly.”

When an element or layer is disposed “on” another element or layer, another layer or another element can be interposed directly on the other element or therebetween. Although the terms “first,” “second,” and the like are used for describing various components, these components are not confined by these terms. These terms are merely used for distinguishing one component from the other components. Therefore, a first component to be mentioned below can be a second component in a technical concept of the present disclosure. Like reference numerals generally denote like elements throughout the specification.

A size and a thickness of each component illustrated in the drawing are illustrated for convenience of description, and the present disclosure is not limited to the size and the thickness of the component illustrated. The features of various embodiments of the present disclosure can be partially or entirely adhered to or combined with each other and can be interlocked and operated in technically various ways, and the embodiments can be performed independently of or in association with each other.

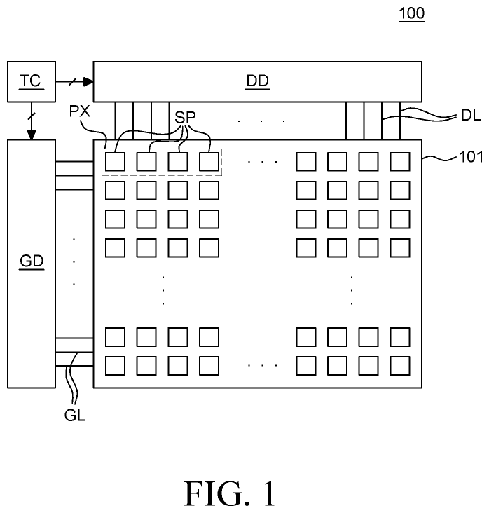

Hereinafter, a display device according to embodiments of the present disclosure will be described in detail with reference to accompanying drawings. In particular, FIG. 1 is a schematic block diagram of a display device 100 according to an embodiment of the present disclosure. Referring to FIG. 1, the display device 100 includes a display panel 101, a gate driver GD, a data driver DD, and a timing controller TC.

The display panel 101 display images and includes various circuits, wiring lines, and light emitting diodes disposed on the substrate. As shown, the display panel 101 is divided by a plurality of data lines DL and a plurality of gate lines GL intersecting each other and includes a plurality of pixels PX connected to the plurality of data lines DL and gate lines GL. In addition, the display panel 101 includes a display area defined by a plurality of pixels PX and a non-display area in which various signal lines or pads are formed. Further, the display panel 101 can be used in a liquid crystal display device, an organic light emitting display device, or an electrophoretic display device. Hereinafter, the display panel 101 is described as a panel used for the OLED device, but is not limited thereto.

In addition, the timing controller TC receives timing signals such as a vertical synchronization signal, a horizontal synchronization signal, a data enable signal, or a dot clock by a receiving circuit such as an LVDS or TMDS interface connected to a host system. The timing controller TC generates timing control signals based on the input timing signal to control the data driver DD and the gate driver GD.

Further, the data driver DD supplies a data voltage to the plurality of sub pixels SP and includes a plurality of source drive ICs (integrated circuits). The plurality of source drive ICs can be supplied with digital video data and a source timing control signal from the timing controller TC. Further, the plurality of source drive ICs converts digital video data into a gamma voltage in response to the source timing control signal to generate a data voltage DATA and can supply the data voltage through the data line DL of the display panel 101. The plurality of source drive ICs can be connected to the data line DL of the display panel 101 by a chip on glass (COG) process or a tape automated bonding (TAB) process. Further, the source drive ICs are formed on the display panel 101 or are formed on a separate PCB substrate to be connected to the display panel 101.

In addition, the gate driver GD supplies a gate signal to the plurality of sub pixels SP and can include a level shifter and a shift register. In more detail, the level shifter shifts a level of a clock signal input at a transistor-transistor-logic (TTL) level from the timing controller TC and then supplies the clock signal to the shift register. Further, the shift register can be formed in the non-display area of the display panel 101, by a GIP manner, but is not limited thereto. The shift register can be configured by a plurality of stages which shifts the gate signal to output, in response to the clock signal and the driving signal. The plurality of stages included in the shift register can sequentially output the gate signal through a plurality of output terminals.

In addition, the display panel 101 can include a plurality of sub pixels SP for emitting different color light. For example, the plurality of sub pixels SP can be a red sub pixel, a green sub pixel, a blue sub pixel, and a white sub pixel, but is not limited thereto. As shown in FIG. 1, the sub pixels SP can configure a pixel PX. That is, the red sub pixel, the green sub pixel, the blue sub pixel, and the white sub pixel can configure one pixel PX and the display panel 101 can include a plurality of pixels PX.

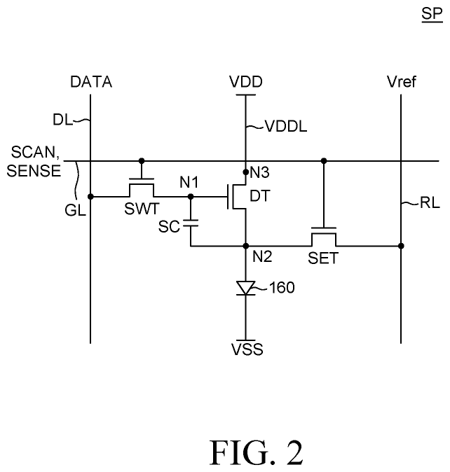

Hereinafter, a driving circuit for driving one sub pixel SP will be described in more detail with reference to FIG. 2. In particular, FIG. 2 is a circuit diagram of a sub pixel of a display device according to an embodiment of the present disclosure. FIG. 2 illustrates a circuit diagram for one sub pixel SP among the plurality of sub pixels SP of the display device 100.

Referring to FIG. 2, the sub pixel SP includes a switching transistor SWT, a sensing transistor SET, a driving transistor DT, a storage capacitor SC, and a light emitting diode 160. The light emitting diode 160 includes an anode, an organic layer, and a cathode. In addition, the organic layer can include various organic layers such as a hole injection layer, a hole transport layer, an organic emission layer, an electron transport layer, and an electron injection layer. Further, as shown, the anode of the light emitting diode 160 is connected to an output terminal of the driving transistor DT and a low potential voltage VSS is applied to the cathode. Even though FIG. 2 illustrates the light emitting diode 160 is an organic light emitting diode, the present disclosure is not limited thereto and an inorganic light emitting diode, that is, an LED can also be used.

Referring to FIG. 2, the switching transistor SWT transmits the data voltage DATA to a first node N1 corresponding to a gate electrode of the driving transistor DT. As shown, the switching transistor SWT incudes a drain electrode connected to the data line DL, a gate electrode connected to the gate line GL, and a source electrode connected to the gate electrode of the driving transistor DT. The switching transistor SWT is turned on by a scan signal SCAN applied from the gate line GL to transmit a data voltage DATA supplied from the data line DL to the first node N1 corresponding to the gate electrode of the driving transistor DT.

As shown in FIG. 2, the driving transistor DT supplies a driving current to the light emitting diode 160 to drive the light emitting diode 160. The driving transistor DT includes a gate electrode corresponding to the first node N1, a source electrode corresponding to a second node N2 and an output terminal, and a drain electrode corresponding to a third node N3 and an input terminal. Further, the gate electrode of the driving transistor DT is connected to the switching transistor SWT, the drain electrode is applied with a high potential voltage VDD by a high potential voltage line VDDL, and the source electrode is connected to the anode of the light emitting diode 160.

In addition, a storage capacitor SC maintains a voltage corresponding to the data voltage DATA for one frame. One electrode of the storage capacitor SC is connected to the first node N1 and the other electrode is connected to the second node N2.

Further, as the driving time of each sub pixel SP is increased, the circuit element such as the driving transistor DT can be degraded. Accordingly, a unique characteristic value of the circuit element such as a driving transistor DT can be changed. Here, the unique characteristic value of the circuit element can include a threshold voltage Vth of the driving transistor DT or a mobility a of the driving transistor DT. The change in the characteristic value of the circuit element can cause a luminance change of the corresponding sub pixel SP. Accordingly, the change in the characteristic value of the circuit element can be used as the same concept as the luminance change of the sub pixel SP.

Further, the degree of the change in the characteristic values between circuit elements of each sub pixel SP can vary depending on a degree of degradation of each circuit element. Such a difference in the changed degree of the characteristic values between the circuit elements can cause a luminance deviation between the sub pixels SP. Accordingly, the characteristic value deviation between circuit elements can be used as the same concept as the luminance deviation between the sub pixels SP. The change in the characteristic values of the circuit elements, that is, the luminance change of the sub pixel SP and the characteristic value deviation between the circuit elements, that is, the luminance deviation between the sub pixels SP can cause problems such as the lowering of the accuracy for luminance expressiveness of the sub pixel SP or screen abnormality.

Therefore, the sub pixel SP of the display device 100 according to the embodiment of the present disclosure can provide a sensing function of sensing a characteristic value for the sub pixel SP and a compensating function of compensating for the characteristic value of the sub pixel SP using the sensing result.

In more detail, as illustrated in FIG. 2, the sub pixel SP can further include a sensing transistor SET to effectively control a voltage state of the source electrode of the driving transistor DT, in addition to the switching transistor SWT, the driving transistor DT, the storage capacitor SC, and the light emitting diode 160.

As shown, the sensing transistor SET is connected between the source electrode of the driving transistor DT and the reference line RL which supplies a reference voltage Vref and a gate electrode is connected to the gate line GL. Therefore, the sensing transistor SET is turned on by the sensing signal SENSE applied through the gate line GL to apply the reference voltage Vref which is supplied through the reference line RL to the source electrode of the driving transistor DT. Further, the sensing transistor SET can be utilized as one of voltage sensing paths for the source electrode of the driving transistor DT.

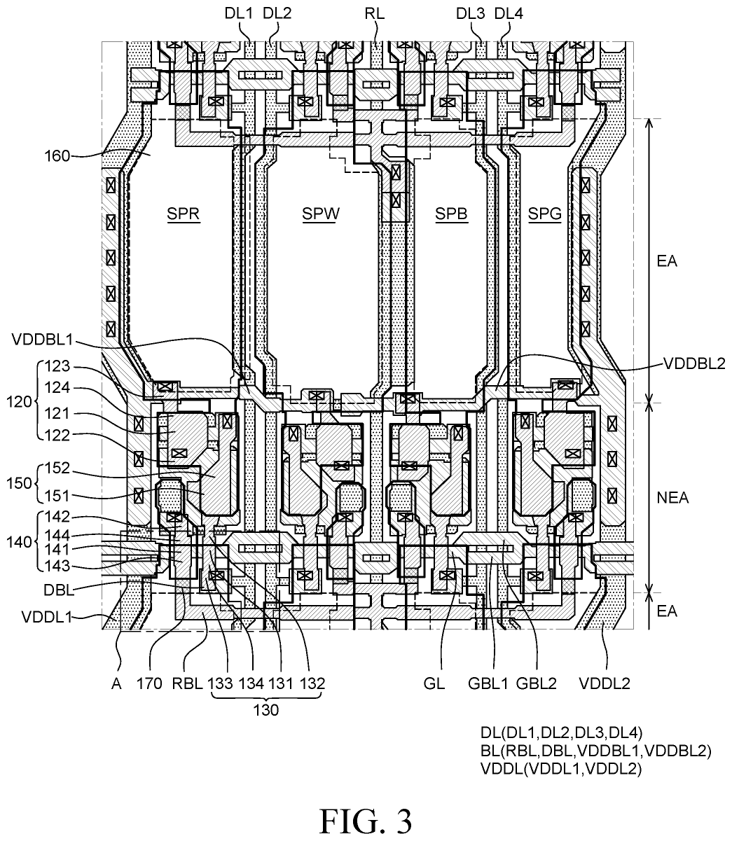

In addition, the switching transistor SWT and the sensing transistor SET of the sub pixel SP can share one gate line GL. That is, the switching transistor SWT and the sensing transistor SET are connected to the same gate line GL to be applied with the same gate signal. However, for the convenience of description, a voltage which is applied to the gate electrode of the switching transistor SWT is referred to as a scan signal SCAN and a voltage which is applied to the gate electrode of the sensing transistor SET is referred to as a sensing signal SENSE. However, the scan signal SCAN and the sensing signal SENSE applied to one sub pixel SP are the same signals which are transmitted from the same gate line GL. Therefore, in FIG. 3, the scan signal SCAN and the sensing signal SENSE are defined and described as gate signals GATE1, GATE2, GATE3 and GATE4.

However, the present disclosure is not limited thereto so that only the switching transistor SWT is connected to the gate line GL and the sensing transistor SET can be connected to a separate sensing line. Therefore, the scan signal SCAN can be applied to the switching transistor SWT through the gate line GL and the sensing signal SENSE can be applied to the sensing transistor SET through the sensing line.

Accordingly, the reference voltage Vref is applied to the source electrode of the driving transistor DT by the sensing transistor SET. Further, a voltage for sensing the threshold voltage Vth of the driving transistor DT or the mobility a of the driving transistor DT is detected by the reference line RL. Also, the data driver DD can compensate for the data voltage DATA in accordance with a variation of the threshold voltage Vth of the driving transistor DT or the mobility a of the driving transistor DT.

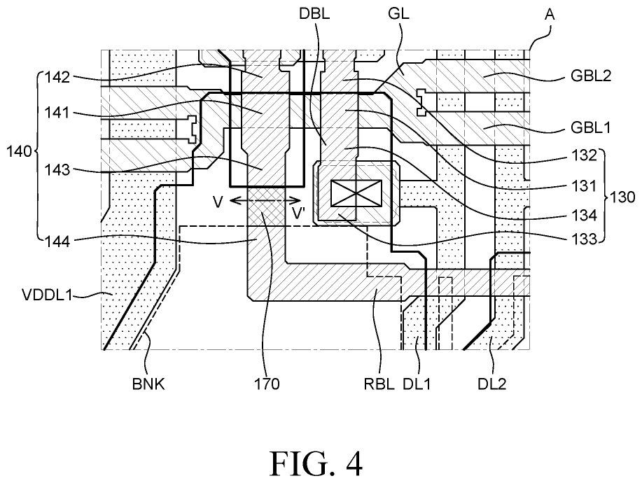

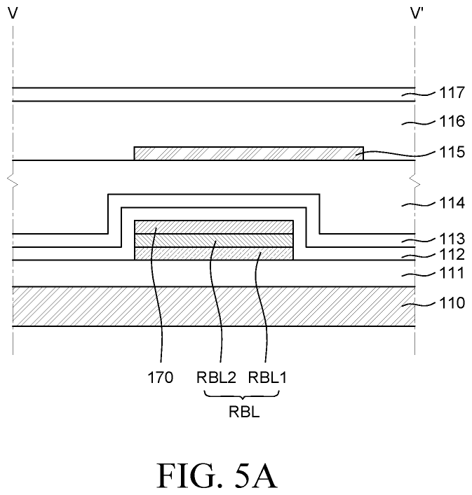

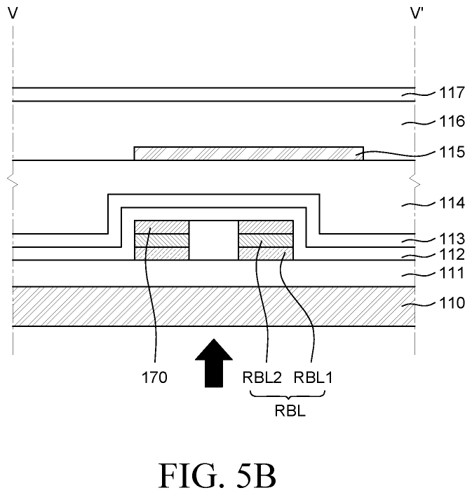

Next, FIG. 3 is an enlarged plan view of a display device according to an embodiment of the present disclosure, FIG. 4 is an enlarged view of an area A of FIG. 3, and FIGS. 5A and 5B are cross-sectional views taken along the line V-V′ of FIG. 4.

Referring to FIGS. 3 to 5B, the display device 100 according to an embodiment of the present disclosure includes a substrate 110, a gate line GL, a data line DL, a high potential power line VDDL, a reference line RL, a light emitting diode 160, a first transistor 120, a second transistor 130, a third transistor 140, a storage capacitor 150, a color filter, a buffer layer 111, a gate insulating layer 112, a passivation layer 113, a planarization layer 114, an anode 115, a bank 116, and an emission layer 117.

In FIG. 4, for the convenience of description, only the third transistor 140, the data lines DL1 and DL2, the gate line GL, the high potential power line VDDL, the data branch line DBL, the reference branch line RBL, and the repair unit 170 are illustrated. In FIGS. 5A and 5B, only a configuration from the substrate 110 to the emission layer 117, among various components of the display device 100, is illustrated for the convenience of description. In particular, FIGS. 5A and 5B are cross-sectional views of a red sub pixel SPR, can be substantially the same as the cross-sectional structures of a white sub pixel SPW, a blue sub pixel SPB and a green sub pixel SPG.

First, referring to FIG. 3, the plurality of sub pixels SP includes a red sub pixel SPR, a white sub pixel SPW, a blue sub pixel SPB, and a green sub pixel SPG, and each sub pixel SP includes an emission area EA and a non-emission area NEA. The emission area EA includes the light emitting diode 160 to independently emit one color light. An emission area EA of the red sub pixel SPR emits red light, an emission area EA of the white sub pixel SPW emits white light, an emission area EA of the blue sub pixel SPB emits blue light, and an emission area EA of the green sub pixel SPG emits green light.

In addition, the non-emission area NEA includes a driving circuit for driving the plurality of light emitting diodes 160 and also, for example, the first transistor 120, the second transistor 130, the third transistor 140, and the storage capacitor 150. In addition, the non-emission area NEA of each of the red sub pixel SPR, the white sub pixel SPW, the blue sub pixel SPB, and the green sub pixel SPG can have substantially similar structure. However, a plurality of sub pixels SP configuring one pixel PX share signal lines. Referring to FIG. 3, the red sub pixel SPR, the white sub pixel SPW, the blue sub pixel SPB, and the green sub pixel SPG share a reference line RL. Further, the red sub pixel SPR and the white sub pixel SPW share a first high potential power line VDDL1 and the blue sub pixel SPB and the green sub pixel SPG share a second high potential power line VDDL2. Accordingly, the red sub pixel SPR and the white sub pixel SPW form one pair and the blue sub pixel SPB and the green sub pixel SPG form one pair to be disposed with a symmetric structure.

As shown in FIG. 3, the plurality of high potential power lines VDDL, the plurality of data lines DL, and the reference line RL extending in a column direction (a Y axis direction) are disposed between the plurality of sub pixels SP on the substrate 110. The plurality of high potential power lines VDDL, the plurality of data lines DL, and the reference line RL can be disposed on the same layer of the substrate 110 and formed of the same material. For example, the plurality of high potential power lines VDDL, the plurality of data lines DL, and the reference line RL can include a conductive material such as copper (Cu), aluminum (Al), molybdenum (Mo), nickel (Ni), titanium (Ti), chrome (Cr), or an alloy thereof, but are not limited thereto.

Further, the plurality of high potential power lines VDDL transmit the power signal to each sub pixel SP and includes a first high potential power line VDDL1 and a second high potential power line VDDL2. Two sub pixels SP which are adjacent to each other in a row direction (X-axis direction) can share one high potential power line VDDL among the plurality of high potential power lines VDDL. For example, the first high potential power line VDDL1 is disposed at a left side of the red sub pixel SPR to transmit the power signal to the first transistors 120 of the red sub pixel SPR and the white sub pixel SPW. Also, the second high potential power line VDDL2 is disposed at a right side of the green sub pixel SPG to transmit the power signal to the first transistors 120 of the blue sub pixel SPB and the green sub pixel SPG.

In addition, the plurality of data lines DL transmit a data signal to each sub pixel SP and includes a first data line DL1, a second data line DL2, a third data line DL3, and a fourth data line DL4. As shown in FIG. 3, the first data line DL1 is disposed between the red sub pixel SPR and the white sub pixel SPW, that is, at a right side of the red sub pixel SPR to transmit the data signal to the second transistor 130 of the red sub pixel SPR. Also, the second data line DL2 is disposed between the first data line DL1 and the white sub pixel SPW, that is, at a left side of the white sub pixel SPW to transmit the data signal to the second transistor 130 of the white sub pixel SPW. Further, the third data line DL3 is disposed between the blue sub pixel SPB and the green sub pixel SPG, that is, at a right side of the blue sub pixel SPB to transmit the data signal to the second transistor 130 of the blue sub pixel SPB. Also, the fourth data line DL4 is disposed between the third data line DL3 and the green sub pixel SPG, that is, at a left side of the green sub pixel SPG to transmit the data signal to the second transistor 130 of the green sub pixel SPG.

In addition, the reference line RL transmits a reference signal to each sub pixel SP and is disposed between the white sub pixel SPW and the blue sub pixel SPB. As shown in FIG. 3, the sub pixels SP forming one pixel share one reference line RL. Also, the reference line RL transmits the reference signal to the third transistors 140 of the red sub pixel SPR, the white sub pixel SPW, the blue sub pixel SPB, and the green sub pixel SPG.

Further, the buffer layer 111 is disposed on the high potential power lines VDDL, the data lines DL, and the reference line RL. The buffer layer 111 reduces permeation of moisture or impurities through the substrate 110. For example, the buffer layer 111 can include a single layer or a double layer of silicon oxide SiOx or silicon nitride SiNx, but is not limited thereto. However, the buffer layer 111 can be omitted depending on a type of substrate 110 or a type of the thin film transistor, but is not limited thereto.

In addition, the first transistor 120 is disposed in the non-emission area NEA of each of the red sub pixel SPR, the white sub pixel SPW, the blue sub pixel SPB, and the green sub pixel SPG. As shown in FIG. 3, the first transistor 120 includes a first gate electrode 121, a first source electrode 122, a first drain electrode 123, and a first active layer 124. The first transistor 120 which is electrically connected to the first electrode of the light emitting diode 160 and the high potential power line VDDL can be a driving transistor DT.

In addition, the first drain electrode 123 is electrically connected to the high potential power lines VDDL. Specifically, the first drain electrodes 123 of the red sub pixel SPR and the white sub pixel SPW can be electrically connected to the first high potential power line VDDL1 through a contact hole formed in the buffer layer 111, and the first drain electrodes 123 of the blue sub pixel SPB and the green sub pixel SPG can be electrically connected to the second high potential power line VDDL2 through a contact hole formed in the buffer layer 111. That is, the first drain electrodes 123 of the red sub pixel SPR and the white sub pixel SPW can be connected to the first high potential power branch line VDDBL1 extending from the first high potential power line VDDL1 through a contact hole, and the first drain electrodes 123 of the blue sub pixel SPB and the green sub pixel SPG can be connected to the second high potential power branch line VDDBL2 extending from the second high potential power line VDDL2 through a contact hole.

In addition, the first active layer 124 can include a semiconductor material such as an oxide semiconductor, amorphous silicon, or polysilicon, but is not limited thereto. For example, when the first active layer 124 includes an oxide semiconductor, the first active layer 124 is formed by a channel region, a source region, and a drain region and the conducted source region and the drain region can serve as a first source electrode 122 and a first drain electrode 123, respectively, but are not limited thereto. Alternatively, an auxiliary metal layer, a transparent oxide layer, or the like is further disposed in a partial area on the first active layer 124 to become conductive to serve as the first source electrode 122 and the first drain electrode 123. Further, the auxiliary metal layer can be configured by an opaque metal layer, such as titanium molybdenum (MoTi) and the transparent oxide layer can be configured by a transparent conductive material, such as tin oxide (TO), indium tin oxide (ITO), indium zinc oxide (IZO), or indium tin zinc oxide (ITZO), but is not limited thereto.

In addition, the first active layer 124 and the first drain electrode 123 of each of the red sub pixel SPR, the white sub pixel SPW, the blue sub pixel SPB, and the green sub pixel SPG can be integrally formed. For example, when a voltage is applied to the first gate electrode 121 of the red sub pixel SPR, the first drain electrode 123 which is integrally formed with the first active layer 124 and is a conductive region in the first active layer 124 transmit the power signal from the first high potential power line VDDL1 to the first active layer 124 and the first source electrode 122. However, the first drain electrode 123 can be defined to be integrally formed with the first high potential power line VDDL1, but is not limited thereto.

In addition, the gate insulating layer 112 is disposed on the first active layer 124. In particular, the gate insulating layer 112 insulates the first gate electrode 121 from the first active layer 124. The gate insulating layer 112 can be disposed only in an area corresponding to conductive layers which are formed of the same material as the first gate electrode 121 by the same process. For example, the gate insulating layer 112 is disposed on the entire surface of the substrate 110 and then removed together when the first gate electrode 121 and the conductive layers disposed on the gate insulating layer 112 are patterned. Also, the gate insulating layer 112 can include a single layer or a double layer of an insulating material such as silicon oxide SiOx or silicon nitride SiNx, but is not limited thereto.

Further, the first gate electrode 121 can be disposed on the gate insulating layer 112 so as to overlap the channel region of the first active layer 124 of each of the red sub pixel SPR, white sub pixel SPW, the blue sub pixel SPB, and the green sub pixel SPG. The first gate electrode 121 can include a conductive material, such as copper (Cu), aluminum (Al), molybdenum (Mo), nickel (Ni), titanium (Ti), chrome (Cr), or an alloy thereof, but is not limited thereto.

In addition, the second transistor 130 is disposed in the non-emission area NEA of each sub pixel SP. As shown in FIG. 3, the second transistor 130 includes a second gate electrode 131, a second source electrode 132, a second drain electrode 133, and a second active layer 134. The second transistor 130 which is electrically connected to the gate line GL, the data line DL, and the first gate electrode 121 of the first transistor 120 can be a switching transistor SWT.

First, the second drain electrode 133 of each sub pixel SP is electrically connected to one data line DL among the plurality of data lines DL. The second drain electrode 133 is integrally formed with the plurality of data lines DL to be formed of the same material as the plurality of data lines DL. However, it is not limited thereto and as illustrated in FIG. 3, the second drain electrode 133 is connected to a data branch line DBL which is connected to a first data line DL1 through the contact hole and is disposed on the same layer and formed with the same material as the first drain electrode 123. Specifically, the second drain electrode 133 can be an area in which the second active layer 134 becomes conducive, similar to the first drain electrode 123.

Also, the second active layer 134 of each sub pixel SP can include a semiconductor material such as an oxide semiconductor, amorphous silicon, or polysilicon, but is not limited thereto. For example, when the second active layer 134 includes an oxide semiconductor, the second active layer 134 is formed by a channel region, a source region, and a drain region and becomes conductive to serve as a second source electrode 132 and a second drain electrode 133. In addition, an auxiliary metal layer, a transparent oxide layer, or the like is further disposed in a partial area on the second active layer 134 to become conductive to serve as the second source electrode 132 and the second drain electrode 133. Further, the auxiliary metal layer can be configured by an opaque metal layer, such as titanium molybdenum (MoTi) and the transparent oxide layer can be configured by a transparent conductive material, such as tin oxide (TO), indium tin oxide (ITO), indium zinc oxide (IZO), or indium tin zinc oxide (ITZO), but is not limited thereto.

In addition, the second gate electrode 131 can be disposed on the gate insulating layer 112 to overlap the channel region of the second active layer 134. The second gate electrode 131 can include a conductive material such as copper (Cu), aluminum (Al), molybdenum (Mo), nickel (Ni), titanium (Ti), chrome (Cr), or an alloy thereof, but is not limited thereto.

The second gate electrode 131 can be the gate line GL. That is, a part of the gate line GL can serve as the second gate electrode 131. The gate line GL can include a conductive material such as copper (Cu), aluminum (Al), molybdenum (Mo), nickel (Ni), titanium (Ti), chrome (Cr), or an alloy thereof, but is not limited thereto.

In addition, the gate line GL transmits a gate signal to each sub pixel SP and extends in a row direction to traverse the plurality of sub pixels SP. For example, the gate line GL extends between the non-emission area NEA and the emission area EA of each sub pixel SP in the row direction to intersect the plurality of high potential power lines VDDL, the plurality of data lines DL, and the reference line RL extending in the column direction. A gate redundancy structure formed in the gate line GL will be described in detail below with reference to FIGS. 4 to 5B.

Also, the third transistor 140 is disposed in the non-emission area NEA of each sub pixel SP. As shown, the third transistor 140 includes a third gate electrode 141, a third source electrode 142, a third drain electrode 143, and a third active layer 144. The third transistor 140 which is electrically connected to the reference line RL, the gate line GL, and the second capacitor electrode 152 of the storage capacitor 150 can be a sensing transistor SET.

In more detail, the third drain electrode 143 is electrically connected to the reference line RL. Specifically, the third drain electrodes 143 of the red sub pixel SPR, the white sub pixel SPW the blue sub pixel SPB, and the green sub pixel SPG can be electrically connected to the reference line RL by extending from the reference line RL. As illustrated in FIG. 3, the third drain electrode 143 can be integrally formed with the reference branch line RBL connected to the reference line RL through the contact hole to be formed with the same material. Specifically, the third drain electrode 143 can be an area in which the third active layer 144 becomes conducive, similar to the second drain electrode 133. The third active layer 144 can be disposed in each sub pixel SP. Also, the third active layer 144 can be formed of a semiconductor material such as an oxide semiconductor, amorphous silicon, or polysilicon, but is not limited thereto. For example, when the third active layer 144 is formed of an oxide semiconductor, the third active layer 144 is formed by a channel region, a source region, and a drain region and becomes conductive to serve as a third source electrode 142 and a third drain electrode 143. In addition, an auxiliary metal layer, a transparent oxide layer, or the like is further disposed in a partial area on the third active layer 144 to become conductive to serve as the third source electrode 142 and the third drain electrode 143. Further, the auxiliary metal layer can be configured by an opaque metal layer, such as titanium molybdenum (MoTi) and the transparent oxide layer can be configured by a transparent conductive material, such as tin oxide (TO), indium tin oxide (ITO), indium zinc oxide (IZO), or indium tin zinc oxide (ITZO), but is not limited thereto.

In addition, the gate insulating layer 112 can be disposed on the third active layer 144 and insulates the third gate electrode 141 from the third active layer 144. The gate insulating layer 112 can be disposed only in an area corresponding to conductive layers which are formed of the same material as the third gate electrode 141 by the same process. For example, the gate insulating layer 112 is disposed on the entire surface of the substrate 110 and then removed together when the third gate electrode 141 and the conductive layers disposed on the gate insulating layer 112 are patterned. Also, the gate insulating layer 112 can include a single layer or a double layer of an insulating material such as silicon oxide SiOx or silicon nitride SiNx, but is not limited thereto.

In each sub pixel SP, the third gate electrode 141 is disposed on the gate insulating layer 112 so as to overlap the channel region of the third active layer 144 on the gate insulating layer 112. The third gate electrode 141 can be the gate line GL. That is, a part of the gate line GL can serve as the third gate electrode 141. The third gate electrode 141 can also include a conductive material, such as copper (Cu), aluminum (Al), molybdenum (Mo), nickel (Ni), titanium (Ti), chrome (Cr), or an alloy thereof, but is not limited thereto.

Further, a storage capacitor 150 is disposed in the non-emission area NEA of each sub pixel SP. In particular, the storage capacitor 150 can store a voltage between the first gate electrode 121 and the first source electrode 122 of the first transistor 120 to allow the light emitting diode 160 to continuously maintain a constant state for one frame. As shown, the storage capacitor 150 includes a first capacitor electrode 151 and a second capacitor electrode 152.

In addition, the first capacitor electrode 151 can be a conductive area of the second active layer 134 in which the semiconductor layer and the transparent oxide layer are laminated. The first capacitor electrode 151 can integrally extend with the second source electrode 132 to be electrically connected to the first gate electrode 121 through a contact hole. That is, the second source electrode 132 of the second transistor 130 and the first gate electrode 121 of the first transistor 120 can be electrically connected to each other through the first capacitor electrode 151. The first capacitor electrode 151 which is integrally formed with the second source electrode 132 can be formed with the same material as the second source electrode 132.

In addition, the second capacitor electrode 152 can be disposed on the substrate 110 so as to overlap the first capacitor electrode 151. The second capacitor electrode 152 can be formed by electrically connecting a light shielding layer disposed at a lowermost portion of the non-emission area NEA and a metal layer disposed on the same layer as the first gate electrode 121 to the first source electrode 122 and the third source electrode 142 through the contact hole.

In summary, the first capacitor electrode 151 of the storage capacitor 150 is a conductive area of the second active layer 134 in which the semiconductor layer and the transparent oxide layer are laminated. The first capacitor electrode 151 integrally extends with the second source electrode 132 to be electrically connected to the first gate electrode 121 of the first transistor 120 and the second source electrode 132 of the second transistor 130 through the contact hole. In the second capacitor electrode 152, a light shielding layer and a metal layer disposed on the same layer as the first gate electrode 121 can be electrically connected to the first source electrode 122 of the first transistor 120 and the third source electrode 142 of the third transistor 140 through the contact hole.

Next, the passivation layer 113 can be disposed on the first transistor 120, the second transistor 130, the third transistor 140, the storage capacitor 150, the plurality of high potential power lines VDDL, the plurality of data lines DL, the reference line RL, and the gate line GL. The passivation layer 113 is an insulating layer for protecting components below the passivation layer 113. For example, the passivation layer 113 can include a single layer or a double layer of silicon oxide SiOx or silicon nitride SiNx, but is not limited thereto. Further, the passivation layer 113 can be omitted depending on the embodiment.

Also, a plurality of color filters are disposed on the passivation layer 113. Specifically, the plurality of color filters can be disposed between the planarization layer 114 and the passivation layer 113. The plurality of color filters includes a red color filter, a green color filter, and a blue color filter. The red color filter is disposed on the emission area EA of the red sub pixel SPR, the blue color filter is disposed on the emission area EA of the blue sub pixel SPB, and the green color filter is disposed on the emission area EA of the green sub pixel SPG. However, the plurality of color filters is not disposed on the emission area EA of the white color filter SPW. In FIG. 3, for the convenience of description, the region of the color filter is not illustrated.

In addition, the planarization layer 114 is disposed on the passivation layer 113 and the color filter and planarizes an upper portion of the substrate 110 on which the first transistor 120, the second transistor 130, the third transistor 140, the storage capacitor 150, the plurality of high potential power lines VDDL, the plurality of data lines DL, the reference line RL, and the gate line GL are disposed. The planarization layer 114 can include an organic material, and for example, a single layer or a double layer of polyimide or photo acryl, but is not limited thereto.

In addition, the light emitting diode 160 is disposed on the planarization layer 114 in each sub pixel SP. The light emitting diode 160 includes an anode 115, an emission layer 117, and a cathode.

In particular, the anode 115 is disposed on the planarization layer 114 in the emission area EA. The anode 115 supplies holes to the emission layer 117 so that the anode can be formed of a conductive material having a high work function. For example, the anode 115 can include a transparent conductive material such as indium tin oxide (ITO) and indium zinc oxide (IZO), but is not limited thereto.

In addition, when the display device 100 is a top emission type, a reflective layer including a metal material having an excellent reflection efficiency, such as aluminum (Al) or silver (Ag) can be added below the anode 115. Therefore, the light emitted from the emission layer 117 is reflected to the anode 115 to be upwardly directed, that is, to be directed to the cathode. In contrast, when the display device 100 is a bottom emission type, the anode 115 can include only a transparent conductive material. Further, the anode 115 is provided in the entire emission area EA and integrally extends to the non-emission area NEA. The anode 115 disposed in the non-emission area NEA is connected to the first source electrode 122 of the first transistor 120 to be applied with an electric signal.

In the emission area EA and the non-emission area NEA, the emission layer 117 is disposed on the anode 115. The emission layer 117 can be formed as one layer over the plurality of sub pixels SP. That is, the emission layers 117 of the sub pixels SP are connected to each other to be integrally formed. The emission layer 117 can include one emission layer or include a plurality of laminated emission layers which emit different color light. The emission layer 117 can further include an organic layer such as a hole injection layer, a hole transport layer, an electron transport layer, and an electron injection layer.

In the emission area EA and the non-emission area NEA, the cathode is disposed on the emission layer 117. The cathode supplies electrons to the emission layer 117 so that the cathode can be formed of a conductive material having a low work function. The cathode can include one layer over the plurality of sub pixels SP. That is, the cathode of each sub pixel SP is connected to be integrally formed. For example, the cathode can include a transparent conductive material such as indium tin oxide (ITO) and indium zinc oxide (IZO) or ytterbium (Yb) alloy and can further include a metal doping layer, but is not limited thereto. The cathode of the light emitting diode 160 can be electrically connected to the low potential power line to be supplied with a low potential power signal.

Next, the gate line GL, the reference branch line RBL, and the data branch line DBL will be described with reference to FIGS. 3 to 5B. First, the gate line GL disposed in the non-emission area NEA transmits a gate signal to each sub pixel SP and extends in a row direction to traverse the sub pixels SP. The gate line GL is sequentially supplied with a scan signal according to the control of the timing controller so that the gate line GL can be referred to as a scan line. In addition, one scan line structure in which the second transistor 130 and the third transistor 140 operate for one gate line GL can be used. However, two scan lines having two gate lines GL can also be applied in in a similar way.

Specifically, the gate line GL can use a gate redundancy structure in an area which intersects a plurality of signal lines. The gate redundancy structure includes the gate line GL branching into two lines only in an area in which the gate line GL and the plurality of signal lines intersect. The gate redundancy structure includes a first bridge line GBL1 extending along the gate line GL and then downwardly branching with respect to the Y-axis direction and a second bridge line GBL2 which is upwardly branched.

Further, the non-emission area NEA includes signal lines extending in the Y-axis direction while intersecting the gate line GL. The signal line which intersecting the gate line GL can be the high potential power line VDDL, the plurality of data lines DL, and the plurality of reference line RL as described above.

In addition, signal lines are configured to transmit the signal to each sub pixel SP and include a branch line BL extending from each signal line. In particular, a branch line BL can include a first high potential power branch line VDDBL1 extending from a first high potential power line VDDL1, a second high potential power branch line VDDBL2 extending from the second high potential power line VDDL2, a data branch line DBL extending from the data line DL, and a reference branch line RBL extending from the reference line RL. The first high potential power branch line VDDBL1 and the second high potential power branch line VDDBL2 are connected to the first high potential power line VDDL1 and the second high potential power line VDDL2, respectively, to apply the high potential voltage to the sub pixels SP. The data branch line DBL is connected to the plurality of data lines DL to apply a data voltage to the plurality of sub pixels SP, and the reference branch line RBL is connected to the reference line RL to apply the reference voltage Vref to the sub pixels SP.

In addition, the branch line BL can be formed integrally from the signal line which is electrically connected. In this instance, the branch line is formed of the same material on the same layer as the signal line so that the branch line BL can include a conductive material, such as copper (Cu), aluminum (Al), molybdenum (Mo), nickel (Ni), titanium (Ti), chrome (Cr), or an alloy thereof, but it is not limited thereto.

However, the branch line BL can be formed on a layer different from the signal line and can be electrically connected through the contact hole. Specifically, as illustrated in FIG. 3, the branch line BL can be an area in which a part of the first active layer 124, the second active layer 134, and the third active layer 144 are conductive.

That is, at least a partial area of the branch line BL can include a lamination structure in which the semiconductor layer and the transparent conductive oxide layer are laminated. The branch line BL can be solely formed with the conductive semiconductor layer in at least a part and in the other part, can be formed with a lamination structure in which a semiconductor layer and a transparent oxide layer formed on the semiconductor layer are laminated. Further, the semiconductor layer can include an oxide semiconductor material such as indium gallium zinc oxide (IGZO), zinc tin oxide (ZTO), or zinc indium oxide (ZIO). Further, the transparent oxide layer includes a transparent conductive material, such as tin oxide (TO), indium tin oxide (ITO), indium zinc oxide (IZO), or indium tin zinc oxide (ITZO). However, they are not limited thereto.

Specifically, among the branch lines BL, the reference branch line RBL is disposed between the white sub pixel SPW and the blue sub pixel SPB and extends in the X-axis direction to transmit the reference voltage to each sub pixel SP. Specifically, the reference branch line RBL extends in the X-axis direction to be connected to the red sub pixel SPR and the green sub pixel SPG and then is bent to the Y-axis direction in each pixel to be disposed in an L-shape. Further, the reference branch line RBL can include only the semiconductor layer RBL1 in a partial area and include a laminated structure in which the semiconductor layer RBL1 and the transparent oxide layer RBL2 are laminated in the other partial area. Specifically, the reference branch line RBL can become conductive by having a laminated structure in which the semiconductor layer RBL1 and the transparent oxide layer RBL2 are laminated from a point which starts extending from the reference line RL before an area in which the third drain electrode 143 is disposed. In addition, when the reference branch line including an opaque material is disposed in the non-emission area NEA, an area of the non-emission area NEA in the pixel is increased.

However, in the display device 100 according to the embodiment of the present disclosure, at least a part of the branch line BL includes a laminated structure in which the semiconductor layer and the transparent oxide layer are laminated. Therefore, the reference branch line RBL passes over the emission area EA. Specifically, the emission area EA is an area defined by the bank BNK and as illustrated in FIG. 4, the laminated structure area of the reference branch line RBL can overlap the emission area EA defined by the bank BNK.

In addition, a defective pixel occurs when a specific line is open during the process of producing the display device 100. Therefore, a repair process is performed by cutting the line of the defective pixel such that the pixel will not emit light. Specifically, the repair process can include a step of irradiating a laser beam onto the first high potential power branch line VDDBL1, the second high potential power branch line VDDBL2, the data branch line DBL, and the reference voltage branch line RBL which transmit the high potential voltage, the data voltage, and the reference voltage to each sub pixel SP. When the laser is irradiated in a repair area of a wiring line including an opaque material, laser energy is received or reflected to disconnect the corresponding wiring line. However, when the wiring line includes a transparent material, a laser in a specific wavelength band used for the repair process is not absorbed so that the repair process is not sufficiently provided.

Therefore, according to an embodiment of the present disclosure, the repair unit 170 is disposed on a partial area of the branch line BL. Referring to FIG. 4, the repair unit 170 is disposed on the reference branch line RBL of the branch line BL corresponding to the repair area. For example, the repair unit 170 is disposed on the reference branch line RBL so as to overlap the repair area. The repair unit 170 includes an opaque metal layer, such as titanium molybdenum (MoTi). Therefore, the laser in a specific wavelength band can be accepted or reflected in an area overlapping the reference branch line RBL so that the repair unit 170 can perform the repair process in the corresponding area.

Further, the repair unit 170 can be disposed on the same layer as the active layer of the transistor disposed in the non-emission area NEA. For example, the repair unit 170 can be disposed on the same layer as the first active layer 124, the second active layer 134, and the third active layer 144 disposed on the buffer layer 111 in the non-emission area NEA. The repair unit 170 can be disposed to overlap the reference branch line RBL disposed on the same layer as the first active layer 124, the second active layer 134, and the third active layer 144.

In addition, the repair unit 170, the reference branch line RBL, and the first active layer 124, the second active layer 134, and the third active layer 144 can be simultaneously formed. After sequentially laminating the semiconductor layer RBL1, the transparent oxide layer RBL2, and the opaque metal layer, the semiconductor layer RBL1, the transparent oxide layer RBL2, and the opaque metal layer in a partial area are removed, respectively, using a multi tone mask. By doing this, the repair unit 170, the reference branch line RBL, the first active layer 124, the second active layer 134, and the third active layer 144 can be formed, respectively.

Specifically, the repair unit 170 can be disposed to be in direct contact with the transparent oxide layer RBL2 where the semiconductor layer RBL1 and the transparent oxide layer RBL2 are laminated. Therefore, when the laser is irradiated by disposing the repair unit 170 to directly contact the reference branch line RBL on which the repair process is performed, the energy of the laser is received or reflected by the repair unit 170 directly contacting the reference branch line RBL. Accordingly, the reference branch line RBL can be more easily disconnected.

Further, the repair unit 170 is preferably spaced apart from the gate line GL with a predetermined interval, because if the repair unit 170 overlaps or is adjacent to the gate line GL, the second transistor 130 and the third transistor 140 which need to be turned off during the driving of the display device 100 are turned on to cause a driving failure problem. Therefore, the repair unit 170 is spaced apart from the gate line GL with a predetermined interval so that the driving failure problem caused by the second transistor 130 and the third transistor 140 which are turned off during the driving of the display device 100 can be suppressed.

Next, FIG. 5A illustrates a structure in which the repair unit 170 and the reference branch line RBL overlap before performing the repair process, and FIG. 5B illustrates a structure after performing the repair process. Referring to FIG. 5B, after performing the repair process by laser, in an area of the reference branch line RBL having a structure in which the semiconductor layer RBL1 and the transparent oxide layer RBL2 are laminated, overlapping the repair unit 170, the reference branch line RBL can be disconnected together with the repair unit 170. That is, when the laser is irradiated in the area overlapping the repair unit 170 and the reference branch line RBL, the repair unit 170 receives and reflects the energy of the laser so that the semiconductor layer RBL1 and the transparent oxide layer RBL2 of the reference branch line RBL can be also disconnected.

Therefore, the current path through which the reference voltage is transmitted to the sub pixel is disconnected so that the sub pixel can become dark by the laser repair process. FIGS. 5A and 5B illustrates that the reference branch line RBL in the area overlapping the repair unit 170 has a laminated structure in which the semiconductor layer RBL1 and the transparent oxide layer RBL2 are laminated. But it is not limited thereto and the reference branch line RBL can have a single layer structure only formed by the semiconductor layer RBL1.

Accordingly, in the display device 100 according to the embodiment of the present disclosure, the repair unit 170 which overlaps the reference branch line RBL is disposed on the reference branch line RBL so as to perform the repair process of the reference branch line RBL while improving the aperture ratio by configuring the reference branch line RBL with a transparent material. Accordingly, it is not necessary to separately dispose an additional metal layer on a layer different from a layer on which the reference branch line RBL is disposed to maximize the aperture ratio.

In addition, to minimize the area of the non-emission area, the branch line can be disposed with a semiconductor layer and a transparent oxide layer disposed on the semiconductor layer. The transparent oxide layer includes a transparent conductive material such as indium zinc oxide (IZO), the entire area of the branch line has a transparency. Therefore, even though the branch line passes through the emission area, the aperture ratio is not affected. However, the branch line including the transparent oxide layer transmits the laser to perform the repair process on the signal line, and an additional metal layer structure is added. Therefore, the additional metal layer formed of the same material on the same layer as the light shielding layer or the gate metal layer is disposed in a partial area of the branch line. This structure has problems in that a contact hole which electrically connects the additional metal layer and the branch line is included and the distance from the surrounding pattern needs to be considered to suppress the short so that the opening area is reduced.

Therefore, in the display device 100 according to the embodiment of the present disclosure, in order to perform the repair process, the repair unit is disposed so as to overlap the reference branch line RBL on the same layer as the reference branch line RBL without disposing the additional metal layer on the same layer as the light shielding layer or the gate metal layer. Therefore, the repair process can be stably performed while ensuring the aperture ratio.

That is, the reference branch line RBL includes a laminated structure in which the semiconductor layer RBL1 and the transparent oxide layer RBL2 on the semiconductor layer RBL1 are laminated. Therefore, even though the reference branch line passes through the emission area EA, the aperture ratio is not affected. Thus, the reference branch line RBL does not need to be disposed only in the non-emission area NEA, so that the design can be freely performed and the aperture ratio can be ensured as compared with the structure of the reference branch line of the related art.

Further, as described above, as the reference branch line RBL includes the transparent material, an additional metal layer required to perform the repair process is not disposed and the repair unit is disposed to directly contact the reference branch line RBL on the same layer as the reference branch line RBL. Therefore, the opening area which is reduced by the additional metal layer can be also ensured. That is, the display device 100 according to the embodiment of the present disclosure can implement stable repair on the reference line RL while maximizing the aperture ratio. The embodiments of the present disclosure include a display device having a substrate including an emission area and a non-emission area, a plurality of sub pixels in the emission area, a driving circuit including a plurality of transistors and wiring lines in the non-emission area for selectively driving each sub pixel, a reference line extending in the emission area between two adjacent sub pixels and including a plurality of branch lines branching from the reference line and being connected to a respective transistor included in the driving circuit for transmitting a reference signal to each subpixel, wherein each branch line comprises a laminated semiconductor layer and transparent oxide layer extending along the emission area and crossing into the non-emission area and an opaque metal layer provided on the transparent oxide layer of a corresponding branch line at a position in the non-emission area.

The opaque metal layer can be corresponded to a repair unit configured to be laser-irradiated to cut the correspond branch line from the respective transistor.

The respective transistor can be comprised a sensing transistor, and the corresponding branch line can include a first part including the laminated semiconductor layer and transparent oxide layer and a second part including the semiconductor layer without the transparent oxide layer such that a drain electrode of the sensing transistor is integrally formed with the semiconductor layer of the second part of the corresponding branch line.

The first part of the corresponding branch line can be overlapped the emission area and the non-emission area.

The repair unit can be disposed in the non-emission area up to an edge of the emission area.

The semiconductor layer can include indium gallium zinc oxide (IGZO), and the transparent oxide layer can include indium zinc oxide (IZO).

The display device can further include at least one high potential power line disposed in the non-emission area and at least one data line disposed in the non-emission area.

The at least one data line can include at least one data branch line branching from the at least one data line to selectively apply a data voltage to the plurality of sub pixels.

The display device can further include at least one gate line including a first bridge line and a second bridge line branched from an area intersecting the at least one high potential power line, the at least one data line, and the one reference line.

The opaque metal layer of the repair unit directly can be contacted the transparent oxide layer of the reference line.

The opaque metal layer of the repair unit can include titanium molybdenum (MoTi).

The repair unit can be on a same layer as an active layer of the respective transistor.

The embodiments of the present disclosure include a method of repairing a defective sub pixel in a display device a display device having a plurality of sub pixels in an emission area, a driving circuit including a plurality of transistors and wiring lines in a non-emission area for selectively driving each sub pixel and a reference line extending in the emission area between two adjacent sub pixels and including a plurality of branch lines branching from the reference line and being connected to a respective transistor included in the driving circuit for transmitting a reference signal to each subpixel, wherein each branch line comprises a laminated semiconductor layer and transparent oxide layer extending along the emission area and crossing into the non-emission area, and an opaque metal layer provided on the transparent oxide layer of a corresponding branch line at a position in the non-emission area, the method comprising, laser cutting the corresponding branch line by irradiating a laser beam onto the opaque metal layer of a corresponding branch line at a position in the non-emission area.

The laser cutting removes the opaque metal layer and the laminated semiconductor layer and transparent oxide layer of the corresponding branch line such that the reference signal is not transmitted to a corresponding subpixel.

The opaque metal layer can be corresponded to a repair unit.

The respective transistor can include a sensing transistor, and the corresponding branch line can include a first part including the laminated semiconductor layer and transparent oxide layer and a second part including the semiconductor layer without the transparent oxide layer such that a drain electrode of the sensing transistor can be integrally formed with the semiconductor layer of the second part of the corresponding branch line.

The first part of the corresponding branch line can be overlapped the emission area and the non-emission area.

The semiconductor layer can include indium gallium zinc oxide (IGZO), and wherein the transparent oxide layer includes indium zinc oxide (IZO).

The opaque metal layer can be directly contacted the transparent oxide layer of the reference line.

The opaque metal layer can include titanium molybdenum (MoTi).

Although the embodiments of the present disclosure have been described in detail with reference to the accompanying drawings, the present disclosure is not limited thereto and can be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an emission area and a non-emission area;
a plurality of sub pixels in the emission area;
a driving circuit including a plurality of transistors and wiring lines in the non-emission area for selectively driving each sub pixel;
a reference line extending in the emission area between two adjacent sub pixels and including a plurality of branch lines branching from the reference line and being connected to a respective transistor included in the driving circuit for transmitting a reference signal to each subpixel, wherein each branch line comprises a laminated semiconductor layer and transparent oxide layer extending along the emission area and crossing into the non-emission area; and
an opaque metal layer provided on the transparent oxide layer of a corresponding branch line at a position in the non-emission area.

2. The display device of claim 1, wherein the opaque metal layer corresponds to a repair unit configured to be laser-irradiated to cut the correspond branch line from the respective transistor.

3. The display device of claim 2, wherein the respective transistor comprises a sensing transistor, and
wherein the corresponding branch line includes a first part including the laminated semiconductor layer and transparent oxide layer and a second part including the semiconductor layer without the transparent oxide layer such that a drain electrode of the sensing transistor is integrally formed with the semiconductor layer of the second part of the corresponding branch line.

4. The display device of claim 3, wherein the first part of the corresponding branch line overlaps the emission area and the non-emission area.

5. The display device of claim 4, wherein the repair unit is disposed in the non-emission area up to an edge of the emission area.

6. The display device of claim 1, wherein the semiconductor layer includes indium gallium zinc oxide (IGZO), and
wherein the transparent oxide layer includes indium zinc oxide (IZO).

7. The display device of claim 1, further comprising:
at least one high potential power line disposed in the non-emission area; and
at least one data line disposed in the non-emission area.

8. The display device of claim 7, wherein the at least one data line includes:
at least one data branch line branching from the at least one data line to selectively apply a data voltage to the plurality of sub pixels.

9. The display device of claim 8, further comprising:
at least one gate line including a first bridge line and a second bridge line branched from an area intersecting the at least one high potential power line, the at least one data line, and the one reference line.

10. The display device of claim 2, wherein the opaque metal layer of the repair unit directly contacts the transparent oxide layer of the reference line.

11. The display device of claim 2, wherein the opaque metal layer of the repair unit includes titanium molybdenum (MoTi).

12. The display device of claim 2, wherein the repair unit is on a same layer as an active layer of the respective transistor.

13. A method of repairing a defective sub pixel in a display device a plurality of sub pixels in an emission area; a driving circuit including a plurality of transistors and wiring lines in a non-emission area for selectively driving each sub pixel; and a reference line extending in the emission area between two adjacent sub pixels and including a plurality of branch lines branching from the reference line and being connected to a respective transistor included in the driving circuit for transmitting a reference signal to each subpixel, wherein each branch line comprises a laminated semiconductor layer and transparent oxide layer extending along the emission area and crossing into the non-emission area, and an opaque metal layer provided on the transparent oxide layer of a corresponding branch line at a position in the non-emission area, the method comprising:
laser cutting the corresponding branch line by irradiating a laser beam onto the opaque metal layer of a corresponding branch line at a position in the non-emission area.

14. The method of claim 13, wherein the laser cutting removes the opaque metal layer and the laminated semiconductor layer and transparent oxide layer of the corresponding branch line such that the reference signal is not transmitted to a corresponding subpixel.

15. The method of claim 13, wherein the opaque metal layer corresponds to a repair unit.

16. The method of claim 13, wherein the respective transistor comprises a sensing transistor, and
wherein the corresponding branch line includes a first part including the laminated semiconductor layer and transparent oxide layer and a second part including the semiconductor layer without the transparent oxide layer such that a drain electrode of the sensing transistor is integrally formed with the semiconductor layer of the second part of the corresponding branch line.

17. The method of claim 16, wherein the first part of the corresponding branch line overlaps the emission area and the non-emission area.

18. The method of claim 13, wherein the semiconductor layer includes indium gallium zinc oxide (IGZO), and
wherein the transparent oxide layer includes indium zinc oxide (IZO).

19. The method of claim 13, wherein the opaque metal layer directly contacts the transparent oxide layer of the reference line.

20. The method of claim 13, wherein the opaque metal layer includes titanium molybdenum (MoTi).
